(19) United States
(12) Patent Application Publication
(10) Pub. No.: US 2020/0008322 A1
(43) Pub. Date: Jan. 2, 2020

(54) RACK SERVER CHASSIS, AND RACK SERVER

(71) Applicant: FUJITSU LIMITED, Kawasaki-shi (JP)

(72) Inventors: Friedrich Köhler, München (DE); Yung-Cheng Lai, München (DE)

(73) Assignee: FUJITSU LIMITED, Kawasaki-shi (JP)

(21) Appl. No.: 16/452,229

(22) Filed: Jun. 25, 2019

(30) Foreign Application Priority Data
Jun. 29, 2018 (DE) 102018115840.8

(51) Int. Cl. H05K 7/20; H05K 7/14

(52) U.S. Cl. CPC H05K 7/20736; H05K 7/20172; H05K 7/1488

(57) ABSTRACT

A rack server chassis, having a housing base and mutually opposite side walls that are disposed on the housing base. The chassis has a first and a second fan fastening plate which are disposed in the rack server chassis and configured in such a manner that between the two fan fastening plates one or a plurality of fans are fixable to the fan fastening plates. The first fan fastening plate is fixed at a predetermined position in the rack server chassis. The chassis has a first fastening means which corresponds to a first assembly position of the second fan fastening plate and by means of which the second fan fastening plate is releasably fixed to the rack server chassis.

The invention relates to a rack server chassis which has a housing base and two mutually opposite side walls. The invention also relates to a rack server which has a rack server housing of this type.

Rack servers which typically have a rack server housing and are pushed into a server rack are known from the prior art. A multiplicity of components of the rack server are arranged within the rack server housing, such as hard drives, printed circuit boards and the like. Rack servers are fitted with one or more fans for cooling the components which are arranged in the interior. In order to ensure optimum cooling for the multiplicity of different rack server systems, fans of different size and different performance and in different numbers are used.

It is an object, on which the present invention is based, to specify a concept for a rack server housing, which takes the wide variety of fans into consideration at least partially.

A rack server chassis is disclosed which has a housing base and mutually opposite side walls that are disposed on said housing base. The rack server chassis has a first and a second fan fastening plate which are disposed in the rack server chassis and configured in such a manner that between the two fastening plates one or a plurality of fans are fixable to the fastening plates. The first fan fastening plate is fixed at a predetermined position in the rack server chassis. The rack server chassis has a first fastening means which corresponds to a first assembly position of the second fan fastening plate and by means of which the second fan fastening plate is releasably fixed to the rack server chassis. The rack server chassis is distinguished by the fact that the rack server chassis has a second fastening means which corresponds to a second assembly position of the second fan fastening plate. As a result, the second fan fastening plate can selectively be releasably assembled at the first assembly position or the second assembly position in the rack server chassis.

The inventors have determined that the cooling for a rack server housing (or rack server chassis) is typically designed for a maximum server expansion level, that is to say for a maximum system performance. This means, in particular, that the number and size of the fans which are used in the system is as a rule overdetermined for a minimum performance expansion level. In other words, high end fans are often installed even in low end systems. In addition, approaches also exist for providing in each case different rack server chassis variants both for high end solutions and low end solutions. As a result, the high costs for the oversized fan configurations in the case of low end systems can at least be reduced. The different chassis variants contribute, however, to increased tool and production costs and logistics costs. In addition, it has been recognized that a changeover at the final customer is made more difficult or is associated with increased costs. Thus, the customer often has to purchase a separate chassis or convert it in a complicated manner for another expansion level.

The invention then provides that the rack server chassis has two fan fastening plates for the fastening, of which one is connected fixedly to the chassis in proper use, whereas the other fan fastening plate can be assembled in a variable manner at two assembly positions in a simple way. Thus, depending on the requirement, the customer can select the first or second assembly position in a rack server chassis, with the result that different fans, that is to say fans of different size or a plurality of fans behind one another, can be installed between the two plates. At the manufacturer, therefore, only one chassis variant has to be stocked which has two fastening means as standard which correspond to the two assembly positions for the second fan fastening plate. As a result, the wide variety in the field of fans and the different expansion levels of server racks are taken into consideration. Fitting on the assembly line and retrofitting on site are therefore possible without problems. Furthermore, tool, production and logistics costs for the manufacturer can be saved considerably.

The fan fastening plates are fastened, for example, transversely with respect to a push-in direction of the rack server chassis in the chassis, for instance to the housing base and the side walls, and extend substantially perpendicularly from the housing base. In other words, the plates form a fan bridge. In other words, the rack server chassis has a fan bridge, in the case of which a variable part of the bridge can be assembled at two positions, whereas the fixed part is connected fixedly to the chassis. The first fan fastening plate is connected, for example, to the chassis in an integrally joined manner, for instance is welded. As an alternative, the first fan fastening plate is riveted fixedly to the chassis or is connected physically in some other way.

In the first assembly position, the second fan fastening plate is at a first spacing from the first fan fastening plate along the push-in direction, and, in the second assembly position, the second fan fastening plate is at a second spacing from the first fan fastening plate along the push-in direction, the second spacing being greater than the first spacing.

The first and/or second fastening means are/is configured or arranged, for example, on the housing base.

The first and/or second fastening means have/has, for example, one or a plurality of screw-fitment points for fixing the second fan fastening plate. As a result, the fan fastening plate can be fixed on the rack server chassis in a simple and releasable manner.

In addition or optionally, the first and/or the second fastening means have/has at least one engagement element which for fixing the second fan fastening plate interacts in a form-fitting manner with a corresponding mating engagement element of the second fan fastening plate.

As a result of the form-fitting interaction, for example, pre-positioning of the second fan fastening plate in the first or second assembly position is possible, with the result that, for example, subsequent screwing of the second fan fastening plate to the rack server chassis is simplified. For example, the second fan fastening plate is brought into form-fitting engagement with the housing base by way of displacement along the housing base, and is subsequently connected fixedly to the housing base by way of screwing.

In accordance with one embodiment, the two fan fastening plates are configured in such a manner that one or a plurality of fans are in each case capable of being hooked into the fan fastening plates such that the fans hooked thereinto extend between two corresponding fan openings which are configured in the two fan fastening plates. Simplified assembly of the fans is ensured by way of being hooked in.

In accordance with one embodiment, the rack server chassis has a support structure which is fixed to the housing base and to the first fan fastening plate such that the first fan fastening plate is physically supported. The supporting structure is, for example, a supporting plate. As a result, the physical stability of the first fan fastening plate is increased.

In accordance with a further aspect, a rack server is disclosed which has a rack server chassis in accordance with one of the above-described embodiments. In addition, the rack server has one or a plurality of fans which between the two fastening plates are fixed to the latter.

The rack server makes substantially the abovementioned advantages and functions possible.

Further advantageous refinements are disclosed in the following, detailed description of one exemplary embodiment. The exemplary embodiment will be described in the following text with reference to the appended figures. Identical or identically acting elements are provided with the same reference signs in all figures.

In the figures:

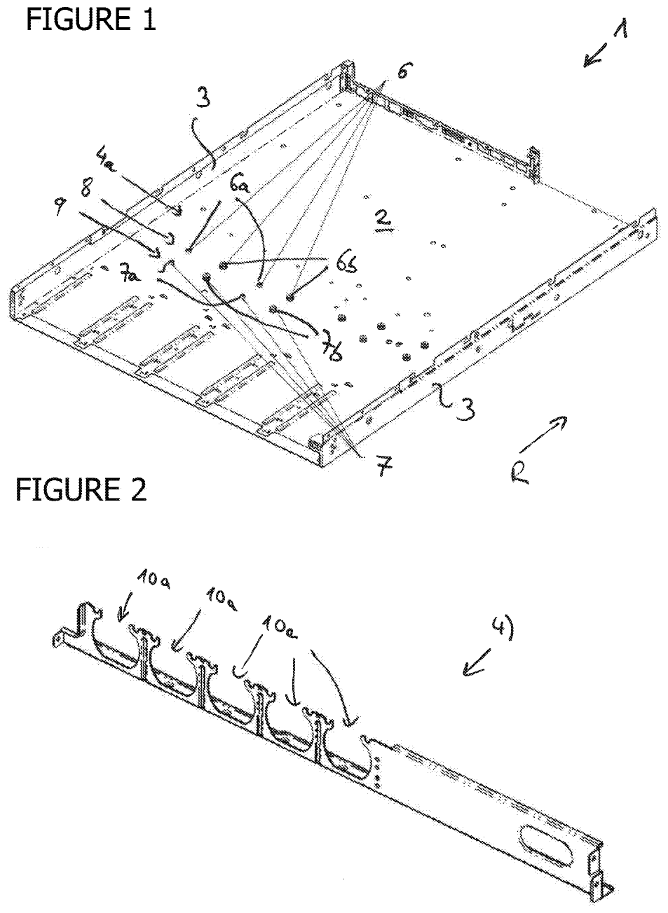

FIG. 1 shows a perspective, diagrammatic view of a rack server chassis,

FIG. 2 shows a perspective, diagrammatic view of a first fan fastening plate for the rack server chassis,

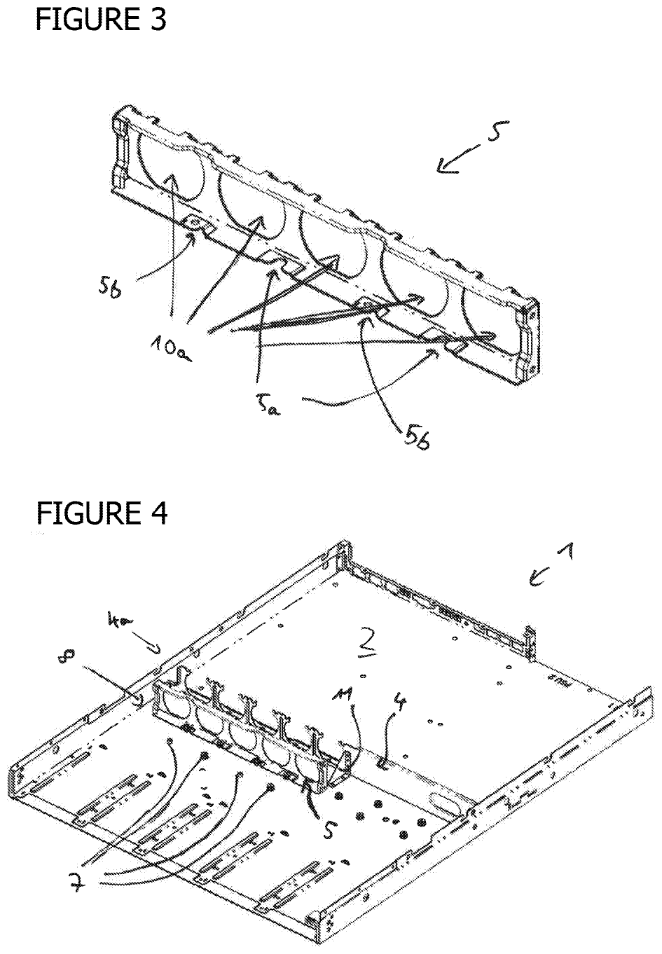

FIG. 3 shows a diagrammatic, perspective view of a second fan fastening plate for the rack server chassis,

FIG. 4 shows a diagrammatic, perspective view of the rack server chassis with installed fan fastening plates, and

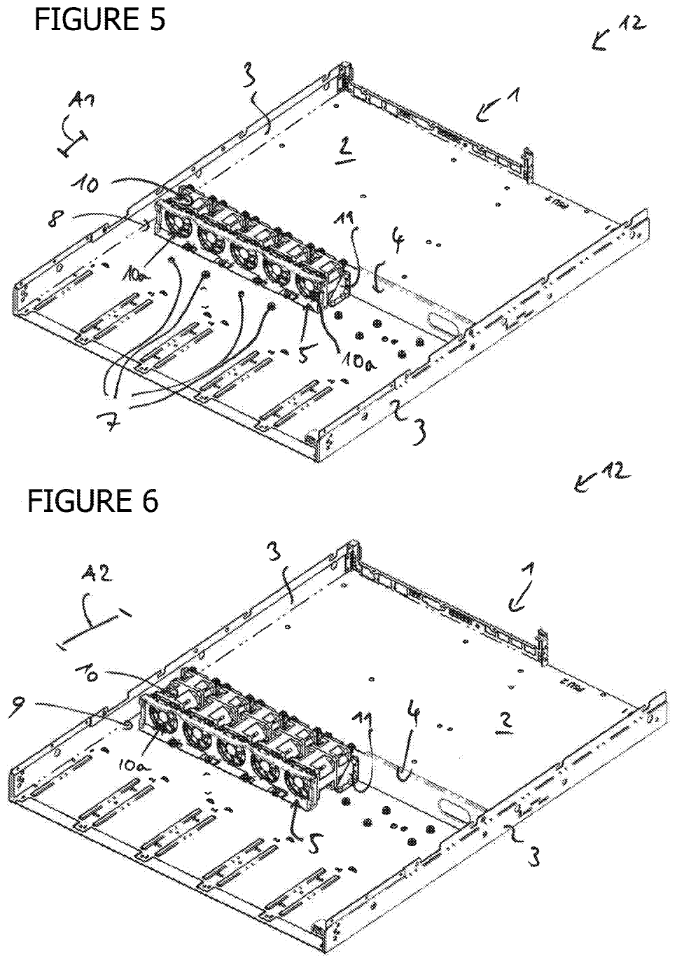

FIGS. 5 and 6 show diagrammatic, perspective views of a rack server with the rack server chassis in two configurations.

FIGS. 1 to 4 diagrammatically show a rack server chassis 1 which has a housing base 2 and two mutually opposite side walls 3 that are disposed on said housing base 2, and fan fastening plates 4 and 5 in individual illustrations and an assembled state. FIG. 1 and the further figures show merely substantially a housing structure, and the illustration of further components in the interior of the rack server chassis 1 and a cover for the rack server chassis 1 are dispensed with for reasons of clarity. The rack server chassis 1 is typically part of a rack server which is pushed into a server rack along the push-in direction R. Components such as hard drives, power supply units and the like are typically arranged in the rack server chassis 1.

The rack server chassis 1 has the first and the second fan fastening plate 4 and 5 which are shown diagrammatically and perspectively separately in FIGS. 2 and 3. The two fan fastening plates 4 and 5 form a fan bridge which serves to mount fans. As shown in the assembled configuration in accordance with FIG. 4, the first fan fastening plate 4 is fastened to a predetermined position 4a. The first fan fastening plate 4 is fastened, in particular, non-releasably to the housing base 2 of the rack server chassis 1 (in proper use).

In addition, the rack server chassis 1 has first and second fastening means 6 and 7 which correspond in each case to a first and second assembly position 8, 9 for the second fan fastening plate 5. The second fan fastening plate 5 is fastened to the housing base 2 in the rack server chassis 1 by means of the fastening means 6 and 7 which are arranged in each case in a row and have one or a plurality of screw-fitment points 6a and 7a, for instance screw threads, and one or a plurality of engagement elements 6b and 7b for a form-fitting connection. The engagement elements 6b, 7b interact with corresponding mating engagement elements 5a of the second fan fastening plate 5 for a form-fitting connection. The screw-fitment points 6a, 7a interact with corresponding bores 5b of the second fan fastening plate 5. In the exemplary embodiment, the second fan fastening plate 5 is placed onto the housing base 2 and is displaced along the latter until a form-fitting connection of the engagement elements 6b or 7b to the corresponding mating engagement elements 5a is achieved and the bores 5b are aligned with the screw-fitment points 6a and 7a.

As a result of the provision of two fastening means 6 and 7, the second fan fastening plate 5 can be assembled selectively at the first or the second assembly position 8 and 9. This makes the advantages and functions which were mentioned at the outset possible.

FIG. 4 shows an assembly configuration, in the case of which the second fan fastening plate 5 is fastened at the first assembly position 8. In this position, the two fan fastening plates 4 and 5 are at a first clear spacing A1 from one another.

In this configuration, first fans 10, for example mono-fans or single fans, can be assembled.

FIG. 5 shows a rack server 12 having a rack server chassis 1 in accordance with the configuration which is shown in FIG. 4. Furthermore, fans 10 which are hooked into the fan fastening plates 4 and 5 and are fastened thereto are shown. The fans 10 are hooked in in such a way that they extend between corresponding fan openings 10a of the two fan fastening plates 4 and 5 (see also FIGS. 2 and 3).

FIG. 6 shows the rack server 12 in a second configuration, in the case of which the second fan fastening plate 5 is fastened at the second assembly position 9 and is at a second spacing A2 from the first fan fastening plate 4, which second spacing A2 is greater than the first spacing A1. In this case, fans 10 which are longer or which are what are known as dual fans or double fans are arranged between the fastening plates 4 and 5.

As can be seen in FIGS. 4 to 6, the rack server chassis 1 additionally has a plate-like supporting structure 11 which is fastened to the housing base 2 and to the first fan fastening plate 4. This ensures an additional physical stability of the first fan fastening plate 4.

### LIST OF REFERENCE SIGNS

1 Rack server chassis
2 Housing base
3 Side wall
4 First fan fastening plate
4a Predetermined position
5 Second fan fastening plate
5a Mating engagement element
5b Bore
6 First fastening means
6a Screw-fitment point
6b Engagement element
7 Second fastening means
7a Screw-fitment point
7b Engagement element
8 First assembly position
9 Second assembly position
10 Fan
10a Fan opening
11 Supporting structure
12 Rack server
A1 First spacing
A2 Second spacing
R Push-in direction

1. A rack server chassis comprising:
a housing base and mutually opposite side walls that are disposed on said housing base;
a first and a second fan fastening plate which are disposed in the rack server chassis and configured in such a manner that between the two fan fastening plates one or a plurality of fans are fixable to the fan fastening plates, wherein the first fan fastening plate is fixed at a predetermined position in the rack server chassis; and
a first fastening means which corresponds to a first assembly position of the second fan fastening plate and by means of which the second fan fastening plate is releasably fixed to the rack server chassis, wherein
the rack server chassis has a second fastening means which corresponds to a second assembly position of the second fan fastening plate such that the second fan fastening plate can selectively be releasably assembled at the first assembly position or the second assembly position in the rack server chassis.

2. The rack server chassis according to claim 1, wherein the first and/or the second fastening means has one or a plurality of screw-fitment points for fixing the second fan fastening plate.

3. The rack server chassis according to claim 1, wherein the first and/or the second fastening means has at least one engagement element which for fixing the second fan fastening plate interacts in a form-fitting manner with a corresponding mating engagement element of the second fan fastening plate.

4. The rack server chassis according to claim 1, wherein the two fan fastening plates are configured in such a manner that one or a plurality of fans are in each case capable of being hooked into the fan fastening plates such that the fans hooked thereinto extend between two corresponding fan openings which are configured in the two fan fastening plates.

5. The rack server chassis according to claim 1, having a support structure which is fixed to the housing base and to the first fan fastening plate such that the first fan fastening plate is physically supported.

6. A rack server, comprising:
a rack server chassis including:
a housing base and mutually opposite side walls that are disposed on said housing base;
a first and a second fan fastening plate which are disposed in the rack server chassis and configured in such a manner that between the two fan fastening plates one or a plurality of fans are fixable to the fan fastening plates, wherein the first fan fastening plate is fixed at a predetermined position in the rack server chassis; and
a first fastening means which corresponds to a first assembly position of the second fan fastening plate and by means of which the second fan fastening plate is releasably fixed to the rack server chassis, wherein the rack server chassis has a second fastening means which corresponds to a second assembly position of the second fan fastening plate such that the second fan fastening plate can selectively be releasably assembled at the first assembly position or the second assembly position in the rack server chassis, and
the one or the plurality of fans which between the two fastening plates are fixed to the latter.
